(19) United States
(12) Patent Application Publication
(10) Pub. No.: US 2017/0294407 A1
(43) Pub. Date: Oct. 12, 2017

(54) PASSIVE ELEMENT PACKAGE AND SEMICONDUCTOR MODULE COMPRISING THE SAME

(71) Applicant: SAMSUNG ELECTRONICS CO., LTD., SUWON-SI (KR)

(72) Inventors: YOUNG-JAE KIM, HWASEONG-SI (KR); BAIK-WOO LEE, GWANGMYEONG-SI (KR); TAE-WOO KANG, SUWON-SI (KR); JAE-GWON JANG, HWASEONG-SI (KR)

(21) Appl. No.: 15/366,484

(22) Filed: Dec. 1, 2016

(30) Foreign Application Priority Data
Apr. 6, 2016 (KR) 10-2016-0042411

(51) Int. Cl. H01L 25/065; H01L 27/08

(52) U.S. Cl. CPC H01L 25/0652; H01L 25/0655; H01L 25/0657; H01L 27/0805; H01L 27/0802; H01L 2225/0651; H01L 2225/06541

(57) ABSTRACT

A passive element package includes a first substrate, first passive elements disposed on the first substrate, a second substrate disposed on the first passive elements, second passive elements disposed on the second substrate, and a sealant that seals the first passive elements and the second passive elements. The passive element package can reduce the size of a semiconductor module that includes the passive element package.

### CROSS-REFERENCE TO RELATED APPLICATION

This application claims priority under 35 USC §119 from, and the benefit of, Korean Patent Application No. 10-2016-0042411, filed on Apr. 6, 2016 in the Korean Intellectual Property Office, the contents of which are herein incorporated by reference in their entirety.

### BACKGROUND

Embodiments of the inventive concept are directed to a package and a semiconductor module, and more particularly, to a passive element package based on a passive element and a semiconductor module including the passive element package.

The demand for reducing the sizes of semiconductor device components and improving electrical characteristics thereof has increased. In general, reducing the size of semiconductor device components reduces the size of a semiconductor module. A semiconductor module may be an electronic component or a superset structure of the electronic component in which at least one active element and at least one passive element are arranged on a single board substrate. A semiconductor module is usually referred to as a module component. Active elements are in the form of a semiconductor chip or a semiconductor package. A semiconductor chip or a semiconductor package may include only the active elements, but may also include both the active elements and passive elements. A passive element may be, for example, a resistor, an inductor, a capacitor, etc. In general, a semiconductor module has more passive elements than active elements, and the passive elements occupy a large portion of a board substrate.

### SUMMARY

Embodiments of the inventive concept can provide a passive element package that can reduce the size of a semiconductor module, and a semiconductor module including the passive element package.

According to an embodiment of the inventive concept, there is provided a passive element package that includes a first substrate; a plurality of first passive elements disposed on the first substrate; a second substrate disposed on the plurality of first passive elements; a plurality of second passive elements disposed on the second substrate; and a sealant that seals the plurality of first passive elements and the plurality of second passive elements.

According to another embodiment of the inventive concept, there is provided a semiconductor module that includes a module substrate; at least one active element package disposed on the module substrate; and a passive element package disposed on the module substrate that has a stack structure in which a plurality of passive elements are stacked.

According to another embodiment of the inventive concept, there is provided a passive element package that includes a plurality of passive elements divided into a plurality of groups, each group including two or more of the plurality of passive elements; and a plurality of stacked substrates, wherein each substrate of the plurality of stacked substrates is disposed between two groups of passive elements to from a stacked structure of that alternates between a group of passive elements and one of the plurality of substrates. Each substrate is electrically connected to an adjacent substrate through wires or substrate connection terminals between the substrates.

### BRIEF DESCRIPTION OF THE DRAWINGS

FIG. 1 is a cross-sectional view of a passive element package according to an embodiment.

FIGS. 2 to 6 are cross-sectional views of passive element packages according to embodiments.

FIG. 7 is a cross-sectional view of a semiconductor module that includes passive elements having stack structures, according to an embodiment.

FIGS. 8 to 14 are cross-sectional views of semiconductor modules that include passive elements having stack structures, according to an embodiment.

FIGS. 15A to 15H are cross-sectional views of a method of manufacturing a passive element package of FIG. 1.

FIGS. 16A to 16D are cross-sectional views of a method of manufacturing a passive element package of FIG. 11, including a sealant for a module.

### DETAILED DESCRIPTION OF THE EMBODIMENTS

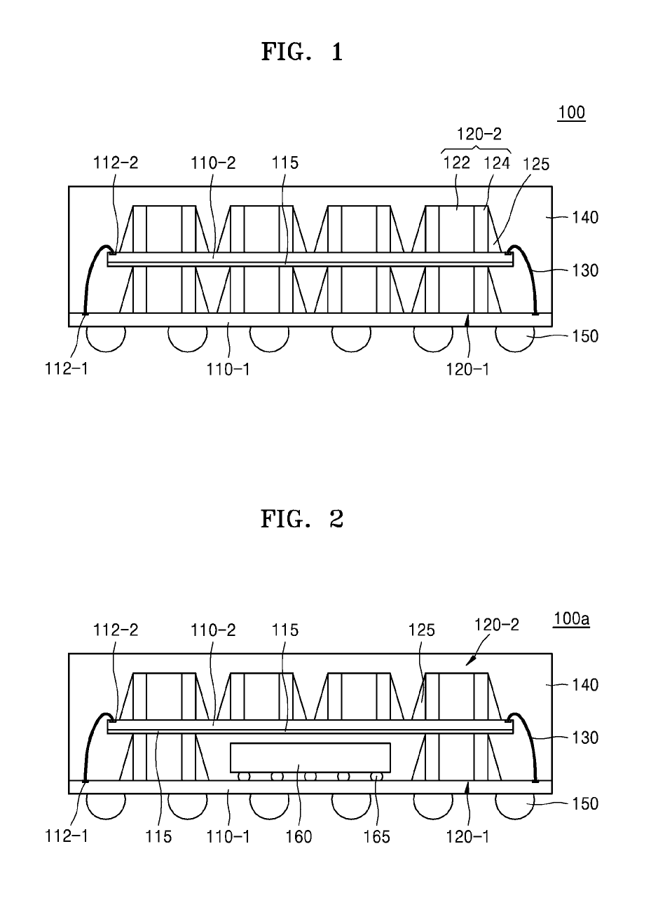

FIG. 1 is a cross-sectional view of a passive element package 100 according to an embodiment.

Referring to FIG. 1, according to embodiments, the passive element package 100 includes substrates 110-1 and 110-2, passive elements 120-1 and 120-2, wires 130, a sealant 140, and external connection terminals 150.

According to embodiments, the substrates 110-1 and 110-2 include first substrate 110-1 on a bottom portion of the passive element package 100 and second substrate 110-2 above the first substrate 110-1. The passive element package 100 according to a present embodiment has a two-storey stack structure in which the passive elements 120-1 and 120-2 are stacked in two layers. Accordingly, the passive element package 100 include two substrates, that is, the first substrate 110-1 and the second substrate 110-2. As shown in FIG. 1, the first substrate 110-1 has a greater area than the second substrate 110-2 to provide a sufficient wire bonding space between the first substrate 110-1 and the second substrate 110-2, a sufficient space for arranging the external connection terminals 150 under the passive element package 100, etc.

According to embodiments, the first and second substrates 110-1 and 110-2 are support substrates on which the passive elements 120-1 and 120-2 are mounted and which include wires formed thereon. For example, the first and second substrates 110-1 and 110-2 include a body layer on which the wires are formed and upper and lower protection layers that cover the body layer and protect the wires. The wires of the first and second substrates 110-1 and 110-2 are electrically connected via solders 125 to the passive elements 120-1 and 120-2 mounted on the first and second substrates 110-1 and 110-2. In addition, the external connection terminals 150 are arranged on a lower surface of the first substrate 110-1, which is opposite to a surface on which the passive elements 120-1 are mounted, and the passive elements 120-1 and 120-2 are electrically connected to the external connection terminals 150 through the wires of the first substrate 110-1.

According to embodiments, the first and second substrates 110-1 and 110-2 may be formed from an organic substrate, an interposer substrate, a ceramic substrate, a glass substrate, a printed circuit board (PCB), etc. In some cases, the first and second substrates 110-1 and 110-2 include active wafers such as silicon wafers.

According to embodiments, the organic substrate is frequently used as a substrate of a chip scale package (CSP), a ball grid array (BGA), or as an intermediate substrate connecting a semiconductor chip to a PCB. An organic substrate may include, for example, an organic material such as epoxy or Bismaleimide Triazine (BT) resin. An organic substrate is inexpensive and has good thermal characteristics and thus has been widely used in the semiconductor package field. According to embodiments, the first and second substrates 110-1 and 110-2 are organic substrates.

In general, an interposer substrate is an intermediate substrate that connects a semiconductor chip to an organic substrate or a PCB and can be classified as an active interposer or a passive interposer. An active interposer includes wires as well as active elements such as a central processing unit (CPU)/logic therein, and a passive interposer includes wires formed therein without active elements. In some cases, a passive interposer includes integrated passive devices. In some embodiments, a Through Silicon Via (TSV), a Redistribution Layer (RDL), etc., is formed on the interposer substrate.

According to embodiments, a PCB includes a body layer, wires, and a protection layer. In general, the body layer is a thin film obtained by pressing phenol, epoxy glass (or FR-4) resin, etc., to a certain thickness. The wires are formed by patterning a copper foil that coats upper and lower surfaces or one surface of the body layer. The protection layer covers the wires, but not pad portions of the wires that are to be connected to the passive elements 120-1 and 120-2, the wire 130, and the external connection terminal 150. In some embodiments, the protection layer includes solder resist (SR). The wires of the upper and lower surfaces of the body layer are electrically connected to each other through via contacts that penetrate the body layer, and the via contacts can be considered to be part of the wires.

For reference, a PCB can be classified as a single-layer PCB that includes wires formed on one side thereof, or a double-layer PCB that includes wires formed on both sides thereof. In addition, at least three layers of copper foil can be formed using prepreg, that is, an insulating material, from which at least three layers of wires can be formed, and thus forming a PCB having multiple layers of wires.

According to embodiments, a substrate bonding layer 115 is formed on a lower surface of the second substrate 110-2. The second substrate 110-2 can be firmly fixed to the passive elements 120-1 above the first substrate 110-1 through the substrate bonding layer 115.

According to embodiments, the passive elements 120-1 and 120-2 include first passive elements 120-1 arranged on the first substrate 110-1 and second passive elements 120-2 arranged on the second substrate 110-2. The first and second passive elements 120-1 and 120-2 include all electronic devices that do not perform active functions, such as amplification or conversion of electrical energy. Each of the first and second passive elements 120-1 and 120-2 includes a main body 122 and an electrode terminal 124. The main body 122 may be, for example, a resistor, an inductor, a capacitor, etc. Depending on what device the main body 122 is, the types of the first and second passive elements 120-1 and 120-2 may be determined. For example, when the main body 122 is a resistor, the first and second passive elements 120-1 and 120-2 are resistive elements. When the main body 122 is a capacitor, the first and second passive elements 120-1 and 120-2 are capacitor elements. In general, the first and second passive elements 120-1 and 120-2 are two-terminal elements, and thus the electrode terminals 124 are arranged on both sides of the main body 122.

According to embodiments, the solders 125 are formed on side surfaces of the electrode terminals 124 and extend between the lower and upper surfaces of the electrode terminals 124. The solders 125 connect the electrode terminals 124 to pads that are exposed on the first and second substrates 110-1 and 110-2 such that the first and second passive elements 120-1 and 120-2 can be fixed to the first and second substrates 110-1 and 110-2 and be electrically connected to the wires of the first and second substrates 110-1 and 110-2. The pads may be part of the wires of the first and second substrates 110-1 and 110-2 or may be separately formed on the wires of the first and second substrates 110-1 and 110-2. The wires of the first and second substrates 110-1 and 110-2 may be covered or may not be covered by the protection layer. If the wires are covered by the protection layer, the pads may be exposed by the protection layer.

According to embodiments, in the passive element package 100, although the first and second passive elements 120-1 and 120-2 may be respectively mounted on the first and second substrates 110-1 and 110-2 through the solders 125 formed on the side surfaces of the electrode terminals 124, mounting structures of the first and second passive elements 120-1 and 120-2 are not limited thereto. For example, the first and second passive elements 120-1 and 120-2 may be directly mounted on the first and second substrates 110-1 and 110-2 through bumps or fine solders between the electrode terminals 124 and the pads. In other words, no solders 125 are formed on the side surfaces of the electrode terminals 124, and the bumps or fine solders are arranged between the lower surfaces of the electrode terminals 124 and the pads of the first and second substrates 110-1 and 110-2. Furthermore, embodiments of of the first and second passive elements 120-1 and 120-2 are not limited to those mounting structures, and based on the types of the first and second passive elements 120-1 and 120-2, the first and second passive elements 120-1 and 120-2 may be respectively mounted on the first and second substrates 110-1 and 110-2 in various ways.

According to embodiments, the wire 130 electrically connects the first substrate 110-1 and the second substrate 110-2 to each other. In detail, the wire 130 connects a substrate pad 112-1 of the first substrate 110-1 and a substrate pad 112-2 of the second substrate 110-2. The second passive elements 120-2 on the second substrate 110-2 are electrically connected to the first substrate 110-1 through the wire 130 and to the external connection terminal 150 through the wires of the first substrate 110-1.

According to embodiments, the sealant 140 seals the first and second substrates 110-1 and 110-2 and the first and second passive elements 120-1 and 120-2. The sealant 140 may include, for example, energetically modified cement (EMC). However, the material of the sealant 140 is not limited thereto. The sealant 140 may include various materials such as epoxy-based materials, thermosetting materials, thermoplastic materials, or UV processing materials. The thermosetting materials may include a phenol-type hardener, an acid-anhydride-type hardener, an amine-type hardener, and an acryl polymer additive. In addition, the sealant 140 may include epoxy and may contain fillers. For example, the sealant 140 may include epoxy-based materials containing about 80% of silica fillers. In some embodiments, no sealant 140 is formed.

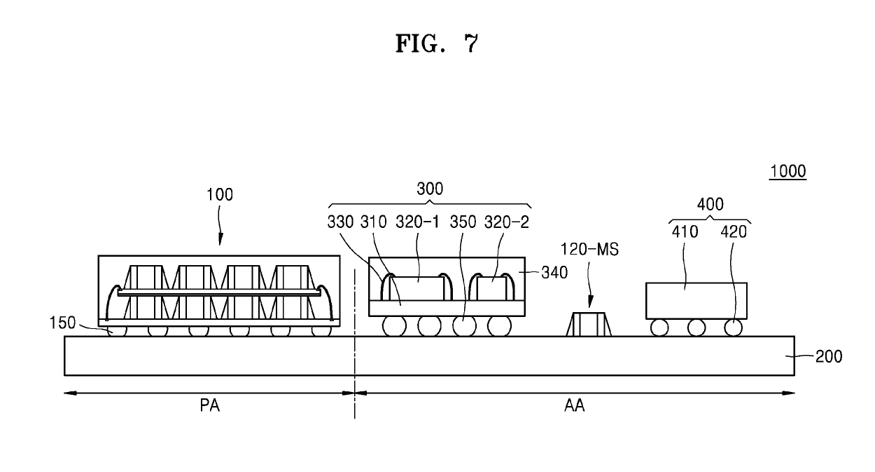

According to embodiments, external connection terminals 150 mount the passive element package 100 on a module substrate, such as the module substrate 200 of FIG. 7, of a semiconductor module, such as the semiconductor module 1000 of FIG. 7. For example, the passive element package 100 can be mounted on the module substrate of the semiconductor module through the external connection terminals 150. The external connection terminals 150 are formed on lower pads of the first substrate 110-1. The lower pads are electrically connected to the wires of the first substrate 110-1. The lower pads may include aluminum (Al), copper (Cu), etc., and may be formed by pulse plating or direct current (DC) plating.

According to embodiments, the external connection terminal 150 may include a conductive material, such as Cu, Al, silver (Ag), tin (Sn), gold (Au), solder, etc. However, the material of the external connection terminal 150 is not limited thereto. The external connection terminal 150 may have a single-layer or multilayer structure. For example, when the external connection terminal 150 has a multilayer structure, the external connection terminals 150 include Cu fillers and solders. When the external connection terminal 150 has a single-layer structure, the external connection terminals 150 include Sn—Ag solders or Cu. In the passive element package 100, the external connection terminal 150 is a solder ball.

According to embodiments, in a semiconductor module such as the semiconductor module 1000 of FIG. 7, the first and second passive elements 120-1 and 120-2 may stably and accurately provide signals and/or power input to active elements. In addition, the first and second passive elements 120-1 and 120-2 can block or remove outside noise to stably provide the signals and/or the power. Since driving voltages, signal frequencies, etc., differ depending on the types of the active elements included in the semiconductor module, the types of I/O pins, or the branch steps that extend from an external power source to the active elements, the number of first and second passive elements 120-1 and 120-2 may be much greater than the number of active elements. Therefore, the active elements occupy a large area of a semiconductor module, and may limit size reductions of a semiconductor module.

According to embodiments, the passive element package 100 has a structure in which the first and second passive elements 120-1 and 120-2 are stacked in respective layers on the first and second substrates 110-1 and 110-2, which reduces the areas of the passive elements. For example, in comparison with a case in which the passive elements are arranged on a single layer, the areas of passive elements that occupy the passive element package 100 can be reduced by half. Therefore, when a semiconductor module includes the passive element package 100, the size of the semiconductor module can be reduced.

FIGS. 2 to 6 are cross-sectional views of passive element packages according to embodiments. The descriptions provided with reference to FIG. 1 will be simplified or omitted.

Referring to FIG. 2, according to an embodiment, a passive element package 100a differs from the passive element package 100 of FIG. 1 in that the passive element package 100a includes an active element 160 above the first substrate 110-1. In detail, according to an embodiment, the active element 160 is mounted on a central portion of the first substrate 110-1 through fine connection terminals 165 in a flip-chip manner, and the first passive elements 120-1 are mounted on outer portions of the first substrate 110-1 through the solders 125, around the active element 160. The fine connection terminals 165 may be, for example, bumps or solder balls. The active element 160 may include an active chip such as a memory chip or a non-memory chip. The memory chip may be one of various types of memory devices, such as dynamic random access memory (DRAM), static RAM (SRAM), flash memory, phase-change RAM (PRAM), resistive RAM (ReRAM), ferroelectrics RAM (FeRAM), magnetic RAM (MRAM), etc. The non-memory chip may be, for example, a device such as a CPU, a microprocessor, or logic.

According to embodiments, the second substrate 110-2 is stacked on the first passive elements 120-1, and the second passive elements 120-2 are mounted on the second substrate 110-2. In addition, the second substrate 110-2 can be electrically connected to the first substrate 110-1 through the wires 130. The active element 160 is spaced apart from the lower surface of the second substrate 110-2. However, in some embodiments, the active element 160 contacts the lower surface of the second substrate 110-2. For example, an upper surface of the active element 160 may adhere and be fixed to the lower surface of the second substrate 110-2 through the substrate bonding layer 115.

According to embodiments, in the passive element package 100a, although one active element 160 is mounted above the first substrate 110-1, at least two active elements 160 can be mounted thereon. In some embodiments, the at least two active elements 160 have a stack structure and are mounted above the first substrate 110-1. In other embodiments, the at least two active elements 160 are spaced apart from each other side by side and mounted above the first substrate 110-1. If the first substrate 110-1 has a small area, no first passive elements 120-1 are mounted above the first substrate 110-1.

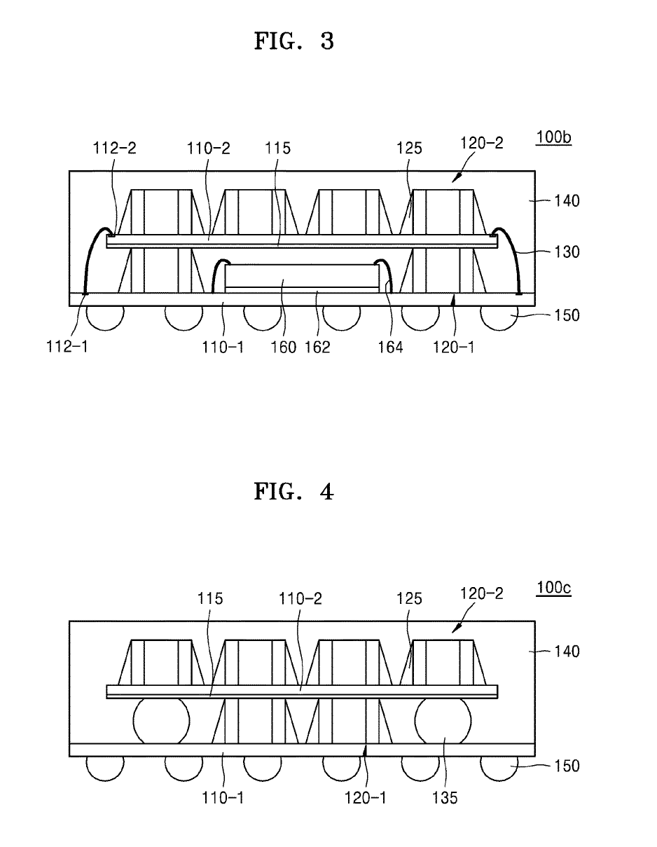

Referring to FIG. 3, according to an embodiment, a passive element package 100b is similar to the passive element package 100a of FIG. 2 in that the passive element package 100b includes the active element 160 above the first substrate 110-1. However, the passive element package 100b differs from the passive element package 100a of FIG. 2 in that the active element 160 of the passive element package 100b is mounted above the first substrate 110-1 using wires 164 in a wire bonding manner. For example, since the active element 160 of the passive element package 100a of FIG. 2 is mounted above the first substrate 110-1 in a flip-chip manner, the active element 160, which has an active surface that faces the first substrate 110-1, is stacked above the first substrate 110-1. On the contrary, since the active element 160 of the passive element package 100b of FIG. 3 is mounted above the first substrate 110-1 in a wire bonding manner, the active element 160, which has an active surface that faces the second substrate 110-2, is stacked above the first substrate 110-1. In addition, the active element 160 may adhere and be fixed to the first substrate 110-1 through a chip bonding layer 162.

Similar to the passive element package 100a of FIG. 2, the second substrate 110-2 is stacked on the first passive elements 120-1, and the second passive elements 120-2 are mounted on the second substrate 110-2. In addition, the second substrate 110-2 is electrically connected to the first substrate 110-1 through the wires 130. Since the active element 160 of the passive element package 100b is mounted above the first substrate 110-1 in a wire bonding manner, the active element 160 and the second substrate 110-2 can be spaced apart from each other by a certain gap therebetween to stably maintain the connection of the wires 164.

Referring to FIG. 4, according to an embodiment, a passive element package 100c differs from the passive element package 100 of FIG. 1 in that the first substrate 110-1 and the second substrate 110-2 are electrically connected to each other through substrate connection terminals 135. In detail, in the passive element package 100 of FIG. 1, the first substrate 110-1 and the second substrate 110-2 are electrically connected to each other through the wires 130, and accordingly, the second passive elements 120-2 on the second substrate 110-2 are electrically connected to the external connection terminals 150 through the wires 130 and the wires of the first substrate 110-1. On the contrary, in the passive element package 100c, the first substrate 110-1 and the second substrate 110-2 are electrically connected to each other through the substrate connection terminals 135 between the first substrate 110-1 and the second substrate 110-2. Therefore, the second passive elements 120-2 on the second substrate 110-2 are electrically connected to the external connection terminals 150 through the substrate connection terminals 135 and the wires of the first substrate 110-1. The substrate connection terminals 135 are arranged on outer portions of the first substrate 110-1, and the first passive elements 120-1 are arranged on a central portion of the first substrate 110-1.

As shown in FIG. 4, since the first passive elements 120-1 are arranged between the first substrate 110-1 and the second substrate 110-2, the substrate connection terminals 135 have heights that correspond to heights of the first passive elements 120-1. Accordingly, the substrate connection terminals 135 are relatively large. For example, the substrate connection terminals 135 may be solder balls. In addition, the substrate connection terminals 135 may have a stack structure in which at least two solder balls are stacked. The substrate connection terminals 135 are electrically connected to the wires of the first substrate 110-1 by contacting pads arranged on an upper surface of the first substrate 110-1 and are electrically connected to the wires of the second substrate 110-2 by contacting pads arranged on a lower surface of the second substrate 110-2.

As in the passive element package 100c according to a present embodiment, if the second substrate 110-2 is stacked above the first substrate 110-1 through the substrate connection terminals 135, no substrate bonding layer 115 need be formed on the lower surface of the second substrate 110-2. In other words, since the substrate connection terminals 135 fix the first substrate 110-1 and the second substrate 110-2 to each other to some extent, the substrate bonding layer 115 may not be formed. However, as shown in FIG. 4, the substrate bonding layer 115 is formed on the lower surface of the second substrate 110-2, and thus the first passive elements 120-1 may adhere and be fixed to the second substrate 110-2 through the substrate bonding layer 115.

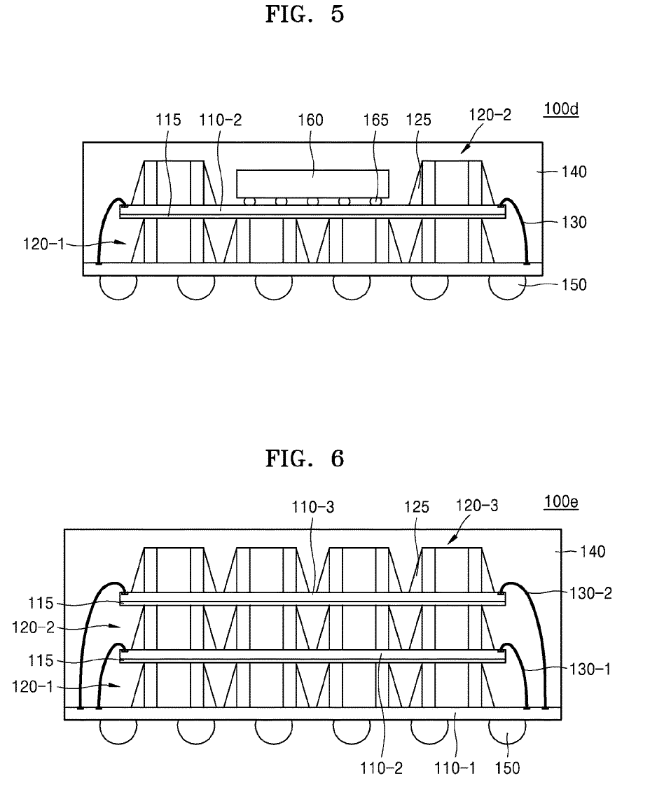

Referring to FIG. 5, according to an embodiment, a passive element package 100d differs from the passive element package 100a of FIG. 2 in that the passive element package 100d includes the active element 160 above the second substrate 110-2. For example, in the passive element package 100a of FIG. 2, the active element 160 is mounted above the first substrate 110-1 in a flip-chip manner. However, in the passive element package 100d of FIG. 5, the active element 160 is mounted above the second substrate 110-2 in a flip-chip manner. Since the active element 160 needs a large number of signal lines and power lines, the number of wires 130 of the passive element package 100d is greater than the number of wires 130 of the passive element packages 100, 100a, and 100b of FIGS. 1 to 3.

In the passive element package 100d according to a present embodiment, although the active element 160 is mounted above the second substrate 110-2 in a flip-chip manner, embodiments are not limited thereto. In other embodiments, the active element 160 is mounted above the second substrate 110-2 in a wire bonding manner.

Referring to FIG. 6, a passive element package 100e according to a present embodiment differs from the passive element packages 100 and 100a to 100d of FIGS. 1 to 5 by having three stacked layers of passive elements 120-1, 120-2, and 120-3. In detail, in the passive element package 100e according to a present embodiment includes the first substrate 110-1, the second substrate 110-2, and a third substrate 110-3. The second substrate 110-2 is stacked on the first passive elements 120-1 through the substrate bonding layer 115, and the third substrate 110-3 is stacked on second passive elements 120-2 through the substrate bonding layer 115. In addition, the first substrate 110-1 and the second substrate 110-2 are electrically connected to each other though a first wire 130-1, and the first substrate 110-1 and the third substrate 110-3 are electrically connected to each other though a second wire 130-2. Materials, structures, etc., of the first to third substrates 110-1 to 110-3 are the same as those in the passive element package 100 of FIG. 1.

According to embodiments, the passive elements 120-1 to 120-3 include the first passive elements 120-1 mounted on the first substrate 110-1, the second passive elements 120-2 mounted on the second substrate 110-2, and third passive elements 120-3 mounted on the third substrate 110-3. As the first substrate 110-1 and the second substrate 110-2 are connected to each other through the first wire 130-1, the second passive elements 120-2 are electrically connected to the external connection terminals 150 through the first wire 130-1 and the wires of the first substrate 110-1. In addition, as the first substrate 110-1 and the third substrate 110-3 are connected to each other through the second wire 130-2, the third passive elements 120-3 are electrically connected to the external connection terminals 150 through the second wire 130-2 and the wires of the first substrate 110-1. Functions, structures, mounting methods, etc., of the first to third passive elements 120-1 to 120-3 are the same as those in the passive element package 100 of FIG. 1.

In the passive element package 100e according to a present embodiment, although the first to third passive elements 120-1 to 120-3 are respectively mounted on the first to third substrates 110-1 to 110-3, a structure of the passive element package 100e is not limited thereto. For example, active elements may be mounted on at least one of the first substrate 110-1, the second substrate 110-2, and the third substrate 110-3. The active elements may be mounted on at least one of the first substrate 110-1, the second substrate 110-2, and the third substrate 110-3 in a flip-chip manner or a wire bonding manner. In addition, in the passive element package 100e, substrate connection terminals may be arranged on at least one of a space between the first substrate 110-1 and the second substrate 110-2, and a space between the second substrate 110-2 and the third substrate 110-3, and the first substrate 110-1 and the second substrate 110-2, or the second substrate 110-2 and the third substrate 110-3 may be electrically connected to each other through the substrate connection terminals.

A passive element package according to embodiments in which passive elements have two or three stacked layers has been described, but embodiments of the inventive concept are not limited thereto. For example, the structure of the passive element package may include passive elements in four or more stacked layers. In addition, the passive element package may include an active element stacked on at least one substrate. In other words, embodiments of the inventive concept include all structures of passive element packages in which passive elements comprise at least two stacked layers.

FIG. 7 is a cross-sectional view of a semiconductor module 1000 that includes passive elements having stack structures, according to an embodiment. The descriptions provided with reference to FIGS. 1 to 6 will be simplified or omitted.

Referring to FIG. 7, the semiconductor module 1000 according to an embodiment includes a module substrate 200, the passive element package 100, an active element package 300, and an active element chip 400.

According to embodiments, the module substrate 200 is a support substrate that forms a frame of the semiconductor module 1000 and is generally based on a PCB. Accordingly, wires are formed in the module substrate 200, which has a multilayer structure. The wires electrically connect the passive element package 100, the active element package 300, and the active element chip 400, which are mounted on the module substrate 200, to each other. In addition, the wires are connected to an external power source and provide a voltage from the external power source to the active element package 300, the active element chip 400, etc. In some cases, the module substrate 200 may be referred to as a system substrate, a main board, etc.

According to embodiments, the passive element package 100 is, for example, the passive element package 100 of FIG. 1. Accordingly, the passive element package 100 has a stack structure in which the first and second passive elements 120-1 and 120-2 are stacked in respective layers on the first and second substrate 110-1 and 110-2. The passive element package 100 has been described with reference to FIG. 1, and thus detailed descriptions thereof are omitted.

According to embodiments, the active element package 300 includes a substrate 310, active elements 320-1 and 320-2, a sealant 340, and external connection terminals 350. Similar to a substrate of a passive element package, the substrate 310 may be formed from an organic substrate, an interposer substrate, a ceramic substrate, a glass substrate, a PCB, etc. According to an embodiment, the substrate 310 is, for example, an organic substrate or a PCB.

According to embodiments, the active elements 320-1 and 320-2 include the first active elements 320-1 and the second active elements 320-2. The first active elements 320-1 and the second active elements 320-2 are spaced apart from each other on the substrate 310 and are mounted on the substrate 310 through a wire 330 in a wire bonding manner. In some embodiments, the first active elements 320-1 and the second active elements 320-2 are mounted on the substrate 310 in a flip-chip manner. In some embodiments, the first active element 320-1 and the second active element 320-2 are, for example, memory devices. In other embodiments, one of the first active element 320-1 and the second active element 320-2 is a memory device, and the other thereof is a non-memory device. The first and second active elements 320-1 and 320-2 may be chips based on active wafers.

According to embodiments, the sealant 340 seals the substrate 310 and the first and second active elements 320-1 and 320-2. The sealant 340 may include, for example, EMC, but the material of the sealant 340 is not limited thereto. The sealant 340 may include, for example, an epoxy-based material, a thermosetting material, a thermoplastic material, a UV processing material, etc.

According to embodiments, the external connection terminals 350 are arranged under the substrate 310 and mount the active element package 300 onto the module substrate 200. The external connection terminal 350 may include a conductive material such as copper (Cu), aluminum (Al), silver (Ag), tin (Sn), gold (Au), or solder. In the active element package 300 according to a present embodiment, the external connection terminal 350 is a solder ball.

In the semiconductor module 1000 according to a present embodiment, the active element package 300 includes two active elements, that is, the first and second active elements 320-1 and 320-2. However, embodiments of the active element package 300 are not limited to that structure. For example, in other embodiments, the active element package 300 may include a single active element or at least three active elements. In addition, in the semiconductor module 1000 according to a present embodiment, although one active element package 300 is mounted on the module substrate 200, at least two active element packages 300 may be mounted on the module substrate 200. Further, the at least two active element packages 300 may have the same structure or different structures.

According to embodiments, the active element chip 400 includes an active element 410 and external connection terminals 420. The active element chip 400 is an active element directly mounted on the module substrate 200 as a chip. That is, the active element 410 is mounted on the module substrate 200 through the external connection terminals 420 in a flip-chip manner. The external connection terminal 420 may be, for example, a bump or a solder ball. In other embodiments, the active element chip 400 is mounted on the module substrate 200 in a wire bonding manner, instead of a flip-chip manner. In some embodiments, the active element chip 400 is a CSP (Chip Scale Package). Depending on the types of the semiconductor module 1000, no active element chip 400 is mounted on the module substrate 200, or at least two active element chips 400 are mounted on the module substrates 200.

According to embodiments, in addition to the first and second passive elements 120-1 and 120-2 that are mounted in the passive element package 100, a substrate passive element 120-MS can be directly mounted on the module substrate 200. If, taking into account a wire structure and its relationship with the active element package 300 or the active element chip 400, it is better to directly place a passive element around the active element package 300 or the active element chip 400, the passive element may be directly mounted on the module substrate 200 instead of in the passive element package 100. A passive element that is directly placed on the module substrate 200 may be referred to as the substrate passive element 120-MS. The substrate passive element 120-MS also includes a main body 122 and electrode terminals 124, and depending on what type of device the main body 122 is, types of the substrate passive element 120-MS can be determined. For example, if the main body 122 is a resistor, the substrate passive element 120-MS is a resistive element, and if the main body 122 is a capacitor, the substrate passive element 120-MS is a capacitor element.

In addition, in some embodiments, at least one slot or socket is located on the module substrate 200, and a slot type PCB can be inserted into and mounted on the at least one slot. Semiconductor chips are mounted on slot type PCBs, and tabs are formed on one edge portion of the PCB. As the edge portion on which the tabs are formed is inserted into the at least one slot, the slot type PCB can be mounted on the module substrate 200.

The semiconductor module 1000 of a present embodiment includes the passive element package 100 on which the passive elements are stacked, and thus a size of the semiconductor module 1000 can be reduced. In detail, in the semiconductor module 1000, an area in which the passive element package 100 is mounted is referred to as a passive element area PA, and an area in which the active element package 300, the active element chip 400, etc., are mounted is referred to as an active element area AA. The active element area AA has substantially the same structure as a general semiconductor module, and thus an area of the active element area AA is not considered to be changed. However, in the case of the passive element area PA, the passive element package 100 is mounted on the module substrate 200, and thus an area of the passive element area PA can be reduced by at least half in comparison with a structure in which the passive elements are directly mounted on the module substrate 200. In other words, in the semiconductor module 1000, an area of the module substrate 200 can be reduced by an area corresponding to a horizontal area of the substrates stacked above the first substrate, in comparison with a structure of a general module substrate. Therefore, the size of the semiconductor module 1000 can be reduced by the total area of the substrates stacked above the first substrate.

According to embodiments, the semiconductor module 1000 forms part of a set-level product or a set-level product itself. If the semiconductor module 1000 forms the set-level product itself, the module substrate 200 may be referred to as a system substrate, a main board, etc., as described above. Examples of a set-level product for which miniaturization is important are a mobile product, a wearable product, and an Internet of Things (IoT) product. To reduce the size of the set-level product, the size of the semiconductor module 1000 should be reduced, and the size reduction can be enabled by a size reduction of the module substrate 200. As described above, the semiconductor module 1000 includes the passive element package 100 in which the passive elements are stacked, and thus the size of the semiconductor module 1000 can be reduced. The size of the set-level product can be therefore reduced.

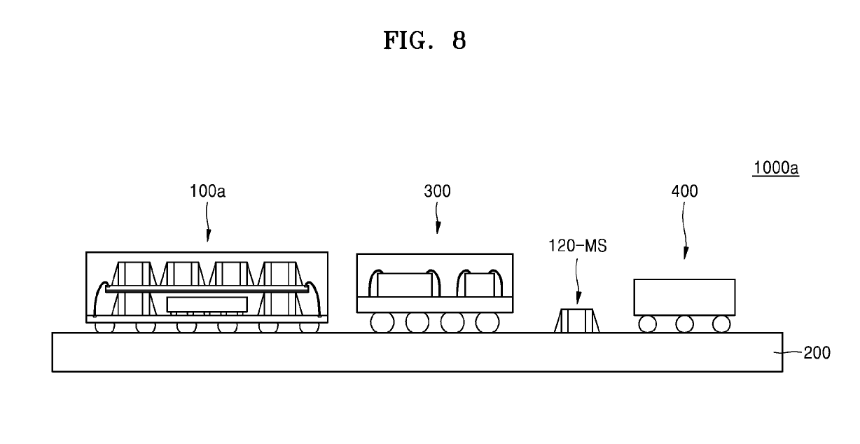

FIGS. 8 to 14 are cross-sectional views of semiconductor modules that include passive elements having stack structures, according to an embodiment. The descriptions already provided with reference to FIGS. 1 to 7 will be simplified or omitted.

Referring to FIG. 8, a semiconductor module 1000a of a present embodiment differs from the semiconductor module 1000 of FIG. 7 in that the semiconductor module 1000a includes the passive element package 100a of FIG. 2. In detail, in the semiconductor module 1000a of a present embodiment, the passive element package 100a includes the active element 160 above the first substrate 110-1. The active element 160 may be mounted above the first substrate 110-1 in a flip-chip manner. The active element 160 may be, for example, a memory device or a non-memory device.

According to embodiments, in the semiconductor module 1000a, the active element 160 is mounted above the first substrate 110-1 in a flip-chip manner, but embodiments of the inventive concept are not limited thereto. In some embodiments, the active element 160 is mounted above the first substrate 110-1 in a wire bonding manner. In other embodiments, the active element 160 is mounted on the second substrate 110-2, instead of the first substrate 110-1, in a flip-chip manner or a wire bonding manner. Furthermore, in still other embodiments, at least two active elements 160 may be mounted above the first substrate 110-1 or the second substrate 110-2.

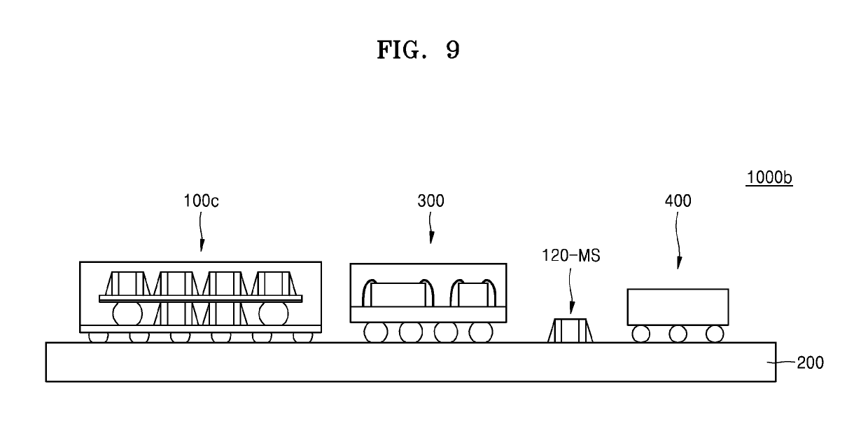

Referring to FIG. 9, a semiconductor module 1000b of a present embodiment differs from the semiconductor module 1000 of FIG. 7 in that the semiconductor module 1000b includes the passive element package 100c of FIG. 4. In detail, in the passive element package 100c of the semiconductor module 1000b, the first substrate 110-1 and the second substrate 110-2 are electrically connected to each other through the substrate connection terminals 135. The substrate connection terminals 135 may be, for example, solder balls, and have substantially the same height as the first passive elements 120-1.

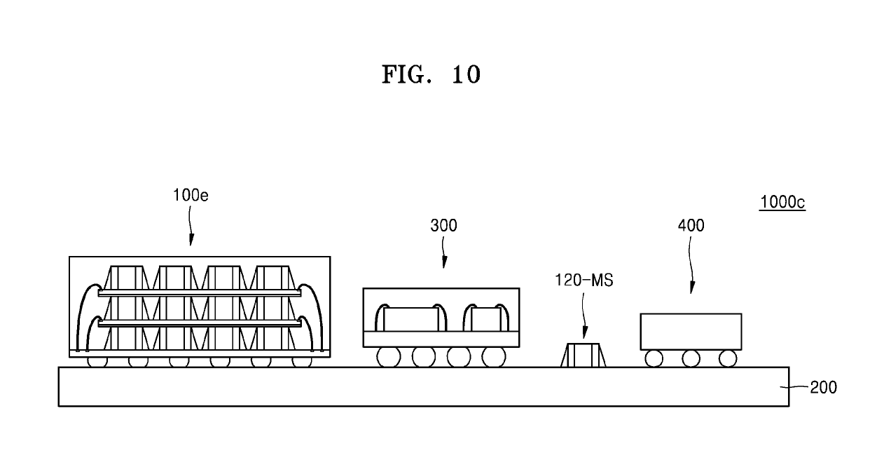

Referring to FIG. 10, a semiconductor module 1000c of a present embodiment differs from the semiconductor module 1000 of FIG. 7 in that the semiconductor module 1000c includes the passive element package 100e of FIG. 6. In detail, in the semiconductor module 1000c, the passive element package 100e has a three layer stack structure of the first to third passive elements 120-1 to 120-3. That is, the first passive elements 120-1 are mounted on the first substrate 110-1, the second substrate 110-2 is stacked on the first passive elements 120-1, the second passive elements 120-2 are mounted on the second substrate 110-2, the third substrate 110-3 is stacked on the second passive elements 120-2, and the third passive elements 120-3 are mounted on the third substrate 110-3. The first substrate 110-1 is electrically connected to the second substrate 110-2 through the first wire 130-1 and to the third substrate 110-3 through the second wire 130-2.

In the semiconductor module 1000c of a present embodiment, the passive element package 100e has a stack structure in which only the first to third passive elements 120-1 and 120-3 are stacked, but embodiments of the passive element package 100e are not limited to that structure. In some embodiments, an active element is mounted on at least one of the first substrate 110-1, the second substrate 110-2, and the third substrate 110-3. In addition, in the semiconductor module 1000c of a present embodiment, substrate connection terminals are arranged on at least one of a space between the first substrate 110-1 and the second substrate 110-2 and a space between the second substrate 110-2 and the third substrate 110-3, and thus, the first substrate 110-1 and the second substrate 110-2 or the second substrate 110-2 and the third substrate 110-3 can be electrically connected to each other through the substrate connection terminals. Furthermore, in the semiconductor module 1000c according to other embodiments, the passive element package 100e has a stack structure in with four or more stacked layers of passive elements.

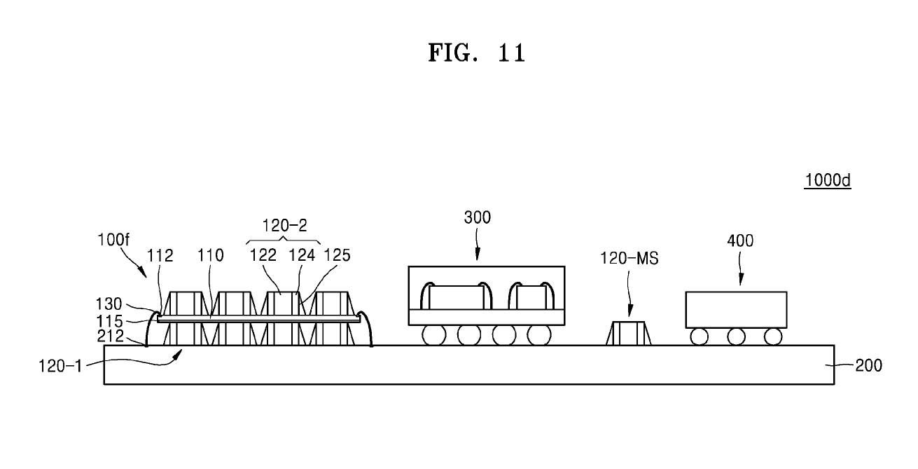

Referring to FIG. 11, a semiconductor module 1000d of a present embodiment differs from the semiconductor modules 1000 and 1000a to 1000c of FIGS. 7 to 10 in terms of a stack structure of the passive element package 100f. In detail, in the semiconductor module 1000d of a present embodiment, the first passive elements 120-1 are directly mounted on the module substrate 200 without a substrate, a substrate 110 is stacked on the first passive elements 120-1, and the second passive elements 120-2 are mounted on the substrate 110.

According to embodiments, the substrate 110 is electrically connected to the module substrate 200 through the wire 130. For example, the wire 130 connects a substrate pad 212 of the module substrate 200 to a substrate pad 112 of the substrate 110. Therefore, the second passive elements 120-2 are electrically connected to wires of the module substrate 200 through the wire 130. In comparing the semiconductor module 1000d of a present embodiment with the semiconductor module 1000 of FIG. 7, a stack structure of the first and second passive elements 120-1 and 120-2 corresponds to a structure of the passive element package 100 in which no first substrate 110-1, no sealant 140, and no external connection terminals 150 are formed.

As described above, according to embodiments, in the semiconductor module 1000d, no substrate 110 and no sealant covering the first and second passive elements 120-1 and 120-2 are formed. In general, when a package structure is formed, a substrate, on which a passive element and/or a semiconductor chip are mounted, is located within a mold, and a sealant is formed through a molding process that injects a molding material into the mold. However, in the semiconductor module 1000d, since the first and second passive elements 120-1 and 120-2 are directly mounted and stacked on the module substrate 200, it may be challenging to form a sealant to seal only the first and second passive elements 120-1 and 120-2. Accordingly, no sealant is formed to seal the substrate 110 and the first and second passive elements 120-1 and 120-2.

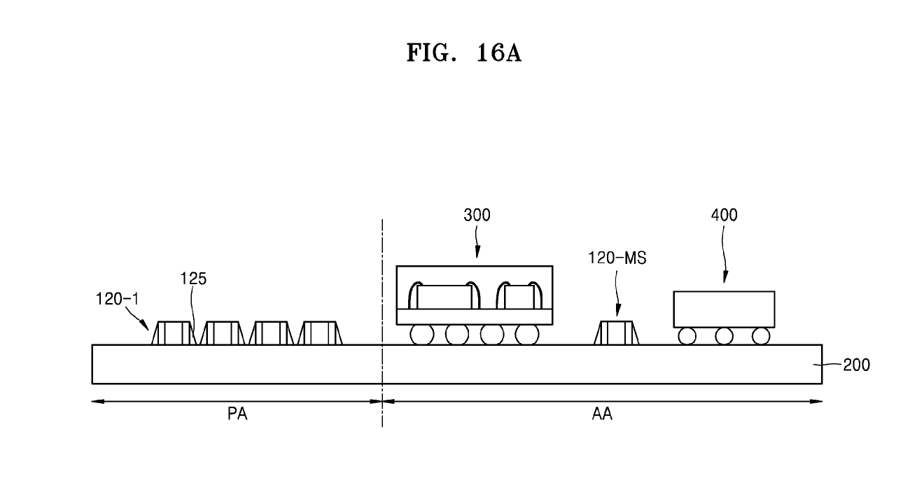

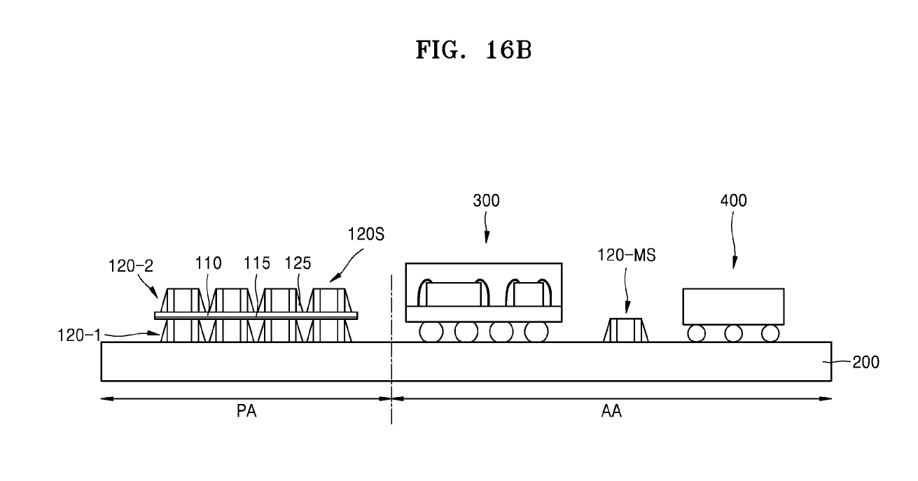

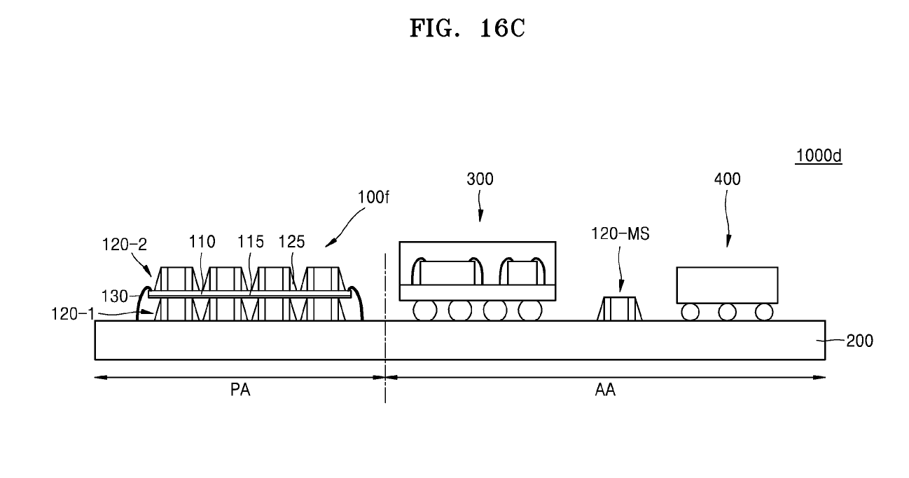

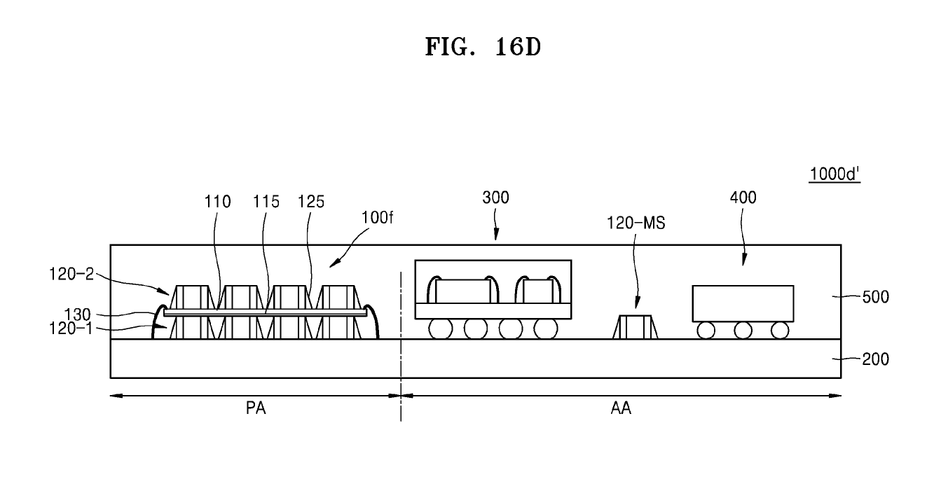

According to other embodiments, in the semiconductor module 1000d, the sealant sealing the substrate 110 and the first and second passive elements 120-1 and 120-2 is formed. In this case, the sealant also seals the active element package 300, the active element chip 400, the substrate passive element 120-MS, etc., in an active element area, such as the active element area AA of FIG. 7. A structure of the sealant will be described with reference to FIG. 16D.

According to embodiments, in the semiconductor module 1000d, although no substrate that supports the first passive elements 120-1 and no sealant are formed, a passive element package 100f has similar structures to the passive element packages 100, 100a, 100c, and 100e of the semiconductor modules 1000 and 1000a to 1000c of FIGS. 7 to 10 in that the first and second passive elements 120-1 and 120-2 are stacked as two layers using the substrate 110. Therefore, in the semiconductor module 1000d, a stack structure in which the substrate 110 and the first and second passive elements 120-1 and 120-2 are stacked is referred to as the passive element package 100f, and in embodiments below, a stack structure in which the substrate 110 and the first and second passive elements 120-1 and 120-2 are stacked is referred to as a passive element package.

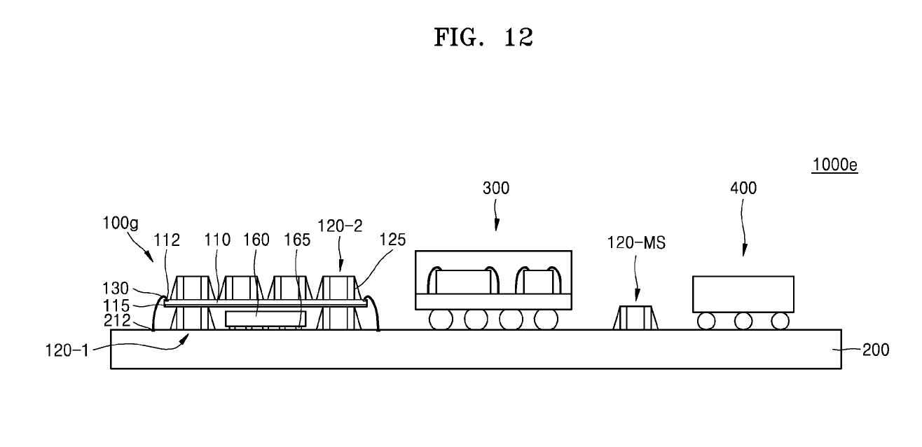

Referring to FIG. 12, a semiconductor module 1000e of a present embodiment is similar to the semiconductor module 1000d of FIG. 11 in that the first and second passive elements 120-1 and 120-2 of a passive element package 100g are directly mounted and stacked on the module substrate 200. However, in the semiconductor module 1000e, the passive element package 100g includes the active element 160 mounted on the module substrate 200. The passive element package 100g of the semiconductor module 1000e has a structure corresponding to the structure of the passive element package 100a of the semiconductor module 1000a of FIG. 8 except that no first substrate 110-1, no sealant 140, and no external connection terminals 150 are formed.

According to embodiments, in the semiconductor module 1000e, the active element 160 is mounted above the module substrate 200 in a flip-chip manner, but embodiments of the inventive concept are not limited thereto. In some embodiments, the active element 160 is mounted above the module substrate 200 in a wire bonding manner. In other embodiments, the active element 160 is mounted above the substrate 110, instead of the module substrate 200, in a flip-chip manner or a wire bonding manner. Furthermore, in still other embodiments, at least two active elements 160 are mounted above the module substrate 200 or the substrate 110.

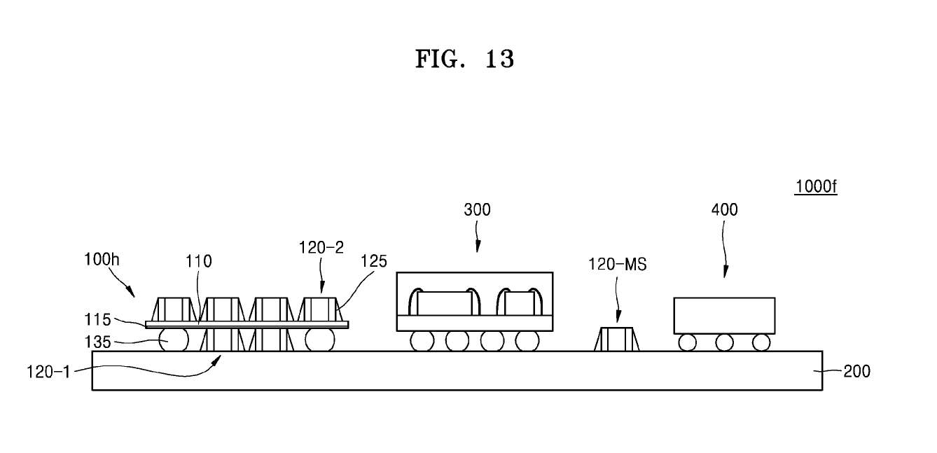

Referring to FIG. 13, a semiconductor module 1000f according to an embodiment is similar to the semiconductor module 1000d of FIG. 11 in that the semiconductor module 1000f has a structure in which first and second passive elements 120-1 and 120-2 of a passive element package 100h are directly mounted and stacked on the module substrate 200. However, in the semiconductor module 1000f, the substrate 110 is electrically connected to the module substrate 200 through the substrate connection terminals 135. The passive element package 100h of the semiconductor module 1000f has a structure corresponding to the structure of the passive element package 100c of the semiconductor module 1000b of FIG. 9 except that no first substrate 110-1, no sealant 140, and no external connection terminals 150 are formed.

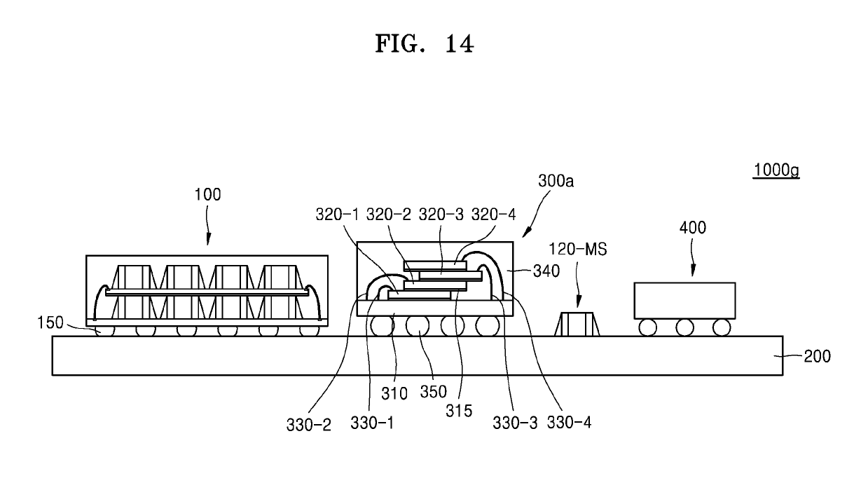

Referring to FIG. 14, a semiconductor module 1000g of a present embodiment differs from the semiconductor module 1000 of FIG. 7 due to a structure of an active element package 300a. In detail, in the semiconductor module 1000g, the active element package 300a includes active elements 320-1 to 320-4 stacked on the substrate 310. For example, the active elements 320-1 to 320-4 include a first active element 320-1, a second active element 320-2, a third active element 320-3, and a fourth active element 320-4 which are sequentially stacked on the substrate 310 through the chip bonding layer 315.

According to embodiments, the first to fourth active elements 320-1 to 320-4 are stacked on the substrate 310 to form a stair going up and to the right, but the fourth active element 320-4 goes left. As the first to fourth active elements 320-1 to 320-4 are stacked on the substrate 310 form a stair, chip pads on upper surfaces of the first to fourth active elements 320-1 to 320-4 may be externally exposed. Alternatively, the first to fourth active elements 320-1 to 320-4 may be stacked on the substrate 310 in a zigzag form, instead of a stair form.

According to some embodiments, the first to fourth active elements 320-1 to 320-4 are memory devices. In other embodiments, any one of the first to fourth active elements 320-1 to 320-4 is a non-memory device, and the others thereof are memory devices. The first to fourth active elements 320-1 to 320-4 may each be a chip based on an active wafer. The first to fourth active elements 320-1 to 320-4 are electrically connected to the substrate 310 through first to fourth wires 330-1 to 330-4. For example, in some embodiments, the first to fourth active elements 320-1 to 320-4 are mounted and stacked on the substrate 310 in a wire bonding manner.

In the semiconductor module 1000g according to a present embodiment, the active element package 300a has a stack structure in which four active elements, that is, the first to fourth active elements 320-1 to 320-4, are stacked, but the number of active elements is not limited to four. In some embodiments, the active element package 300a has two or three active elements stacked in a stack structure. In other embodiments, the active element package 300a has at least five active elements stacked in a stack structure. In the active element package 300a of the semiconductor module 1000g according to a present embodiment, the first to fourth active elements 320-1 to 320-4 are electrically connected to the substrate 310 through the first to fourth wires 330-1 to 330-4. However, embodiments of the inventive concept are not limited thereto. The first to fourth active elements 320-1 to 320-4 may be electrically connected to the substrate 310 through through-silicon-vias (TSVs).

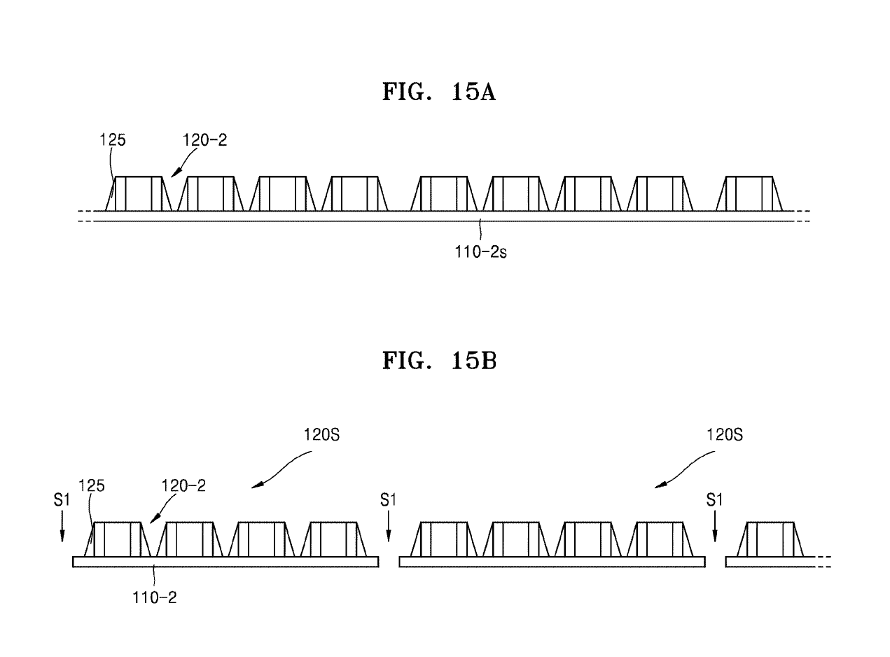

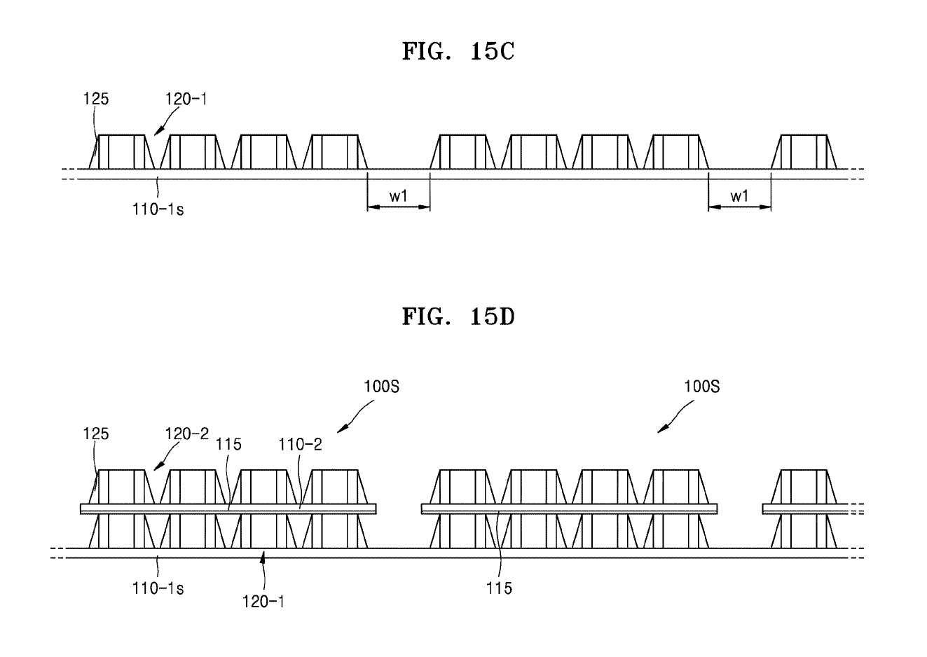

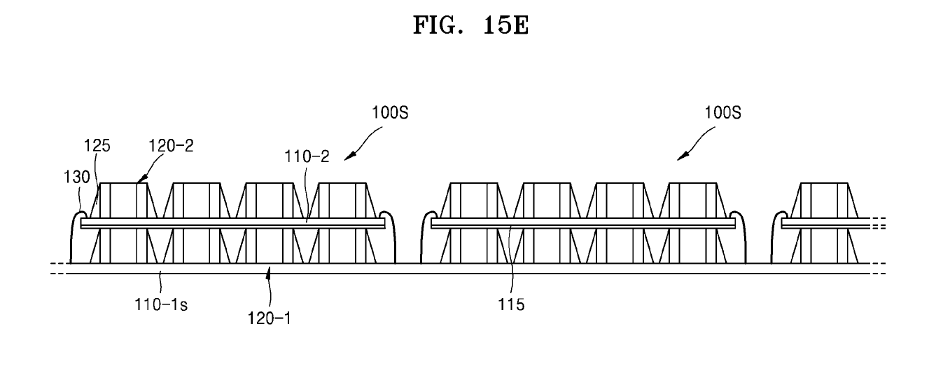

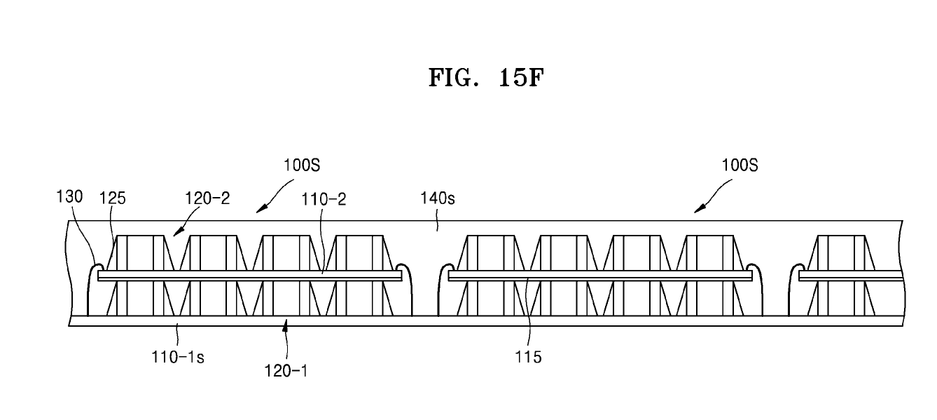

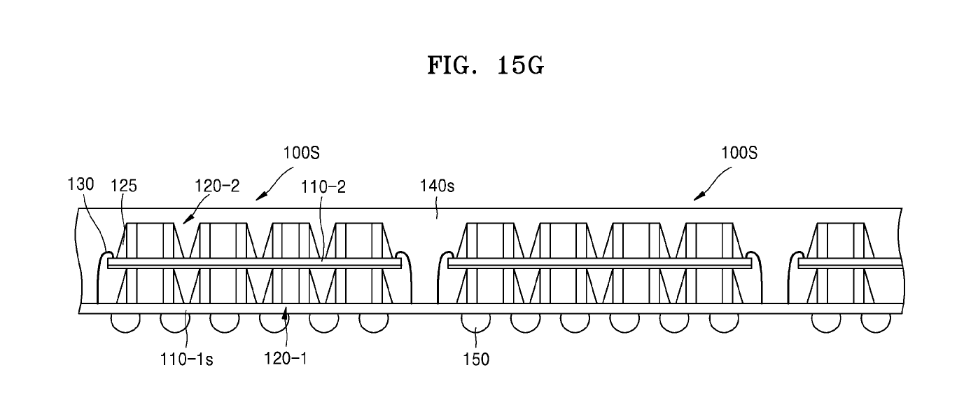

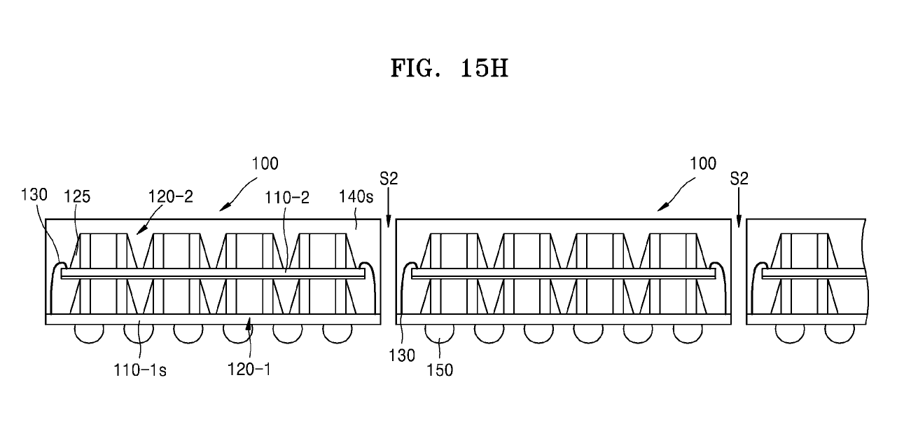

FIGS. 15A to 15H are cross-sectional views of a method of manufacturing the passive element package of FIG. 1. The descriptions provided with reference to FIGS. 1 to 6 will be simplified or omitted.

Referring to FIG. 15A, according to embodiments, the second passive elements 120-2 are mounted on a second plate substrate 110-2s. The second passive elements 120-2 are fixed to the second plate substrate 110-2s through the solders 125 and electrically connected to wires of the second plate substrate 110-2s.

Referring to FIG. 15B, according to embodiments, after the second passive elements 120-2 are mounted on the second plate substrate 110-2s, as indicated by arrows S1, the second plate substrate 110-2s is separated into upper-layer structures 120S through a sawing process. The upper-layer structure 120S includes, for example, the second substrate 110-2 and the second passive elements 120-2 mounted on the second substrate 110-2.

Referring to FIG. 15C, according to embodiments, the first passive elements 120-1 are mounted on a first plate substrate 110-1s. The first passive elements 120-1 are fixed to the first plate substrate 110-1s and electrically connected to wires of the first plate substrate 110-1s through the solders 125. Mounting the first passive elements 120-1 on the first plate substrate 110-1s may be performed simultaneously with or performed before mounting the second passive elements 120-2 on the second plate substrate 110-2s.

According to embodiments, the first passive elements 120-1 are arranged in groups on the first plate substrate 110-1s that are separated by first intervals W1. The first intervals W1 are used as wire connection spaces when the upper-layer structures 120S are stacked on the first passive elements 120-1 mounted on the first plate substrate 110-1s, and the second substrate 110-2 is connected to the first substrate 110-1 through the wires. Due to the first intervals W1 on the first plate substrate 110-1s, the area of the first substrate 110-1 is greater than that of the second substrate 110-2 in the passive element package 100 of FIG. 1.

Referring to FIG. 15D, according to embodiments, the upper-layer structures 120S are stacked on the first passive elements 120-1 on the first plate substrate 110-1s. The upper-layer structure 120S is adhered and fixed to the first passive elements 120-1 through the substrate bonding layer 115. As the upper-layer structures 120S are stacked on the first passive elements 120-1, two layer stack structures 100S are formed.

Referring to FIG. 15E, according to embodiments, the second substrate 110-2 is connected to the first plate substrate 110-1s via the wire 130, thus the wires of the second substrate 110-2 are electrically connected to wires of the first plate substrate 110-1s. The connection through the wires 130 is performed for each group of stack structures 100S.

Referring to FIG. 15F, according to embodiments, after the second substrate 110-2 is connected to the first plate substrate 110-1s via the wire 130, a sealant 140s is formed that seals the first and second passive elements 120-1 and 120-2. The sealant 140s is formed through a molding process of locating the first plate substrate 110-1s in a mold and injecting a molding material into the mold.

Referring to FIG. 15G, according to embodiments, the external connection terminals 150 are formed on a lower surface of the first plate substrate 110-1s. The external connection terminals 150 are arranged in groups on the lower surface of the first plate substrate 110-1s that substantially correspond to the groups of stack structures 100S, and the groups of connection terminals 150 are separated by intervals that substantially correspond to the first interval W1.

Referring to FIG. 15H, according to embodiments, as indicated by arrows S2, the stack structures 100S of FIG. 15G are separated into respective stack structures through a sawing process, and thus the passive element package 100 of FIG. 1 can be completely formed.

For reference, the passive element packages 100a, 100b, and 100d of FIGS. 2, 3, and 5 can be completely formed by mounting active elements on the first and second plate substrates 110-1s and 110-2s in a wire bonding manner or a flip-chip manner when the first and second passive elements 120-1 and 120-2 are mounted thereon and then by performing the processes of FIGS. 15B and 15D to 15H. In addition, the passive element package 100c of FIG. 4 can be completely formed by stacking the upper-layer structures 120S on the first passive elements 120-1 through the substrate connection terminals 135 and performing the processes of FIGS. 15F to 15H. Furthermore, in the passive element package 100c of FIG. 4, the first passive elements 120-1 are mounted on the first plate substrate 110-1s except for regions where the substrate connection terminals 15 are arranged, and the second passive elements 120-2 are mounted as shown in FIG. 15D. The passive element package 100e of FIG. 6 can be completely formed by stacking the upper-layer structures 120S of FIG. 15B in three layers and then by performing the subsequent processes.

FIGS. 16A to 16D are cross-sectional views of a method of manufacturing the passive element package of FIG. 11, which includes a module sealant. The descriptions provided with reference to FIGS. 1 to 15H will be simplified or omitted.

Referring to FIG. 16A, according to embodiments, an upper layer structure, such as the upper-layer structure 120S of FIG. 15B, in which the second passive elements 120-2 are mounted on the substrate 110 is formed through the processes of FIGS. 15A and 15B. Then, the active element package 300 and the active element chip 400 are mounted on the active element area AA of the module substrate 200 using the external connection terminals 350 and 420. The first passive elements 120-1 are mounted on the passive element area PA by using the solders 125. In some embodiments, substrate passive element 120-MS is mounted on the active element area AA when the first passive elements 120-1 are mounted on the passive element area PA. However, in other embodiments, the substrate passive element 120-MS is separately from the first passive elements 120-1.

According to some embodiments, after the active element package 300 and the active element chip 400 are mounted, the first passive elements 120-1 are mounted. Alternatively, according to other embodiments, after the first passive elements 120-1 are mounted, the active element package 300 and the active element chip 400 are mounted.

Referring to FIG. 16B, according to embodiments, the upper-layer structures 120S are stacked on the first passive elements 120-1 using the substrate bonding layer 115. As described above, the upper-layer structures 120S include the substrate 110 and the second passive elements 120-2.

Referring to FIG. 16C, according to embodiments, the module substrate 200 and the substrate 110 are electrically connected to each other through the wires 130. Accordingly, the second passive elements 120-2 are electrically connected to the module substrate 200 via the wires 130 and the wires of the substrate 110. A structure of the passive element package 100f of FIG. 11 is completely formed by connecting the module substrate 200 to the substrate 110 via the wires 130. In addition, the semiconductor module 1000d of FIG. 11 can be completely formed by completing the passive element package 100f.

For reference, the semiconductor module 1000 and 1000a to 1000c of FIGS. 7 to 10 can be completely formed by mounting the passive element packages 100, 100a, 100c, and 100e on the module substrate 200 using the external connection terminals 150 instead of mounting the first passive elements 120-1 on the module substrate 200 during the process of FIG. 16A and then performing the processes of FIGS. 16B and 16C. In addition, the semiconductor module 1000e of FIG. 12 can be completely formed by mounting the first passive elements 120-1 as well as the active element 160 on the module substrate 200 during the process of FIG. 16A and performing the processes of FIGS. 16B and 16C. The semiconductor module 1000f of FIG. 13 can be completely formed by mounting the first passive elements 120-1 on the module substrate 200 except on the area where the substrate connection terminals 135 are formed during the process of FIG. 16A and then by mounting and stacking the upper-layer structures 120S on the first passive elements 120-1 using the substrate connection terminals 135 during the processes of FIGS. 16B and 16C.

Referring to FIG. 16D, according to embodiments, after the module substrate 200 is connected to the substrate 110 through the wires 130, a module sealant 500 is formed that seals the passive element package 100f, the active element package 300, the active element chip 400, and the substrate passive element 120-MS. The module sealant 500 is formed through a molding process of locating the module substrate 200 in a mold and injecting a molding material in the mold. The module sealant 500 can protect the passive element package 100f, the active element package 300, the active element chip 400, and the substrate passive element 120-MS from external physical or chemical damage or contamination.

The module sealant 500 may also be formed in the semiconductor modules 1000e and 1000f of FIGS. 12 and 13. Moreover, the sealant 500 may be formed in the semiconductor modules 1000, 1000a to 1000c, and 1000g of FIGS. 7 to 10 and 14.

While embodiments of the inventive concept has been particularly shown and described with reference to exemplary embodiments thereof, it will be understood that various changes in form and details may be made therein without departing from the spirit and scope of the following claims.

1. A passive element package comprising:
a first substrate;
a plurality of first passive elements disposed on the first substrate;
a second substrate disposed on the plurality of first passive elements;
a plurality of second passive elements disposed on the second substrate; and
a sealant that seals the plurality of first passive elements and the plurality of second passive elements.

2. The passive element package of claim 1, wherein the first substrate is electrically connected to the second substrate through wires between the first substrate and the second substrate.

3. The passive element package of claim 1, further comprising at least one active element disposed on one of the first substrate or second substrate,
wherein the at least one active element is disposed among the plurality of first passive elements on the first substrate or the plurality of second passive elements on the second substrate.

4. The passive element package of claim 1, further comprising external connection terminals disposed on a lower surface of the first substrate.

5. The passive element package of claim 1, further comprising:
at least one upper substrate disposed on upper surfaces of the plurality of second passive elements; and
a plurality of upper passive elements disposed on the at least one upper substrate.

6. A semiconductor module comprising:
a module substrate;
at least one active element package disposed on the module substrate; and
a passive element package disposed on the module substrate, said passive element package having a stack structure in which a plurality of passive elements are stacked.

7. The semiconductor module of claim 6, wherein the passive element package comprises
a first substrate disposed on the module substrate, a second substrate disposed on the first substrate, and the plurality of passive elements, and a sealant that seals the plurality of passive elements,
the plurality of passive elements comprise a plurality of first passive elements disposed on the first substrate and a plurality of second passive elements disposed on the second substrate, and
the passive element package is mounted on the module substrate through external connection terminals arranged on a lower surface of the first substrate.

8. The semiconductor module of claim 7, wherein the first substrate is electrically connected to the second substrate through wires between the first substrate and the second substrate.

9. The semiconductor module of claim 7, wherein the passive element package further comprises at least one second active element disposed on the first substrate among the plurality of first passive elements.

10. The semiconductor module of claim 7, wherein the passive element package further comprises at least one upper substrate disposed on the plurality of second passive elements and a plurality of upper passive elements disposed on the at least one upper substrate.

11. The semiconductor module of claim 6, wherein the passive element package comprises:
a plurality of first passive elements disposed on the module substrate;
a first substrate disposed on the first passive elements; and
a plurality of second passive elements disposed on the first substrate.

12. The semiconductor module of claim 11, wherein the first substrate is electrically connected to the module substrate through wires between the first substrate and the module substrate.

13. The semiconductor module of claim 11, wherein the passive element package further comprises at least one second active element disposed above the module substrate under the first substrate and among the plurality of first passive element.

14. The semiconductor module of claim 6, further comprising a module sealant that seals the at least one active element package and the passive element package.

15. The semiconductor module of claim 6, wherein the at least one active element package has a package structure or a semiconductor chip structure.

16. A passive element package comprising:
a plurality of passive elements divided into a plurality of groups, each group including two or more of the plurality of passive elements; and
a plurality of stacked substrates, wherein each substrate of the plurality of stacked substrates is disposed between two groups of passive elements to form a stacked structure of that alternates between a group of passive elements and one of the plurality of substrates,
wherein each substrate is electrically connected to an adjacent substrate through wires between the substrates.

17. The passive element package of claim 16, further comprising a sealant that seals the plurality of passive elements.

18. The passive element package of claim 16, further comprising at least one active element disposed between the two or more passive elements of a group of passive elements that is electrically connected to one of the plurality of substrates adjacent to said a group of passive elements.

19. The passive element package of claim 16, further comprising a bottom substrate and external connection terminals disposed on a lower surface of the bottom substrate.

20. The passive element package of claim 16, further comprising a substrate bonding layer on one surface of each substrate, wherein passive elements of a group of passive elements adjacent to the substrate bonding layer of a substrate are fixed to said substrate by the substrate bonding layer.
